(19) United States
(12) Patent Application Publication
(10) Pub. No.: US 2025/0176075 A1
(43) Pub. Date: May 29, 2025

(54) CERAMIC HEATER

(71) Applicant: NGK INSULATORS, LTD., Nagoya-City (JP)

(72) Inventor: Keisuke TAKASHIMA, Nagoya-City (JP)

(73) Assignee: NGK INSULATORS, LTD., Nagoya-City (JP)

(21) Appl. No.: 18/731,440

(22) Filed: Jun. 3, 2024

Related U.S. Application Data
(63) Continuation of application No. PCT/JP2023/042804, filed on Nov. 29, 2023.

(51) Int. Cl. H05B 3/28; G05D 23/22

(52) U.S. Cl. CPC H05B 3/283; G05D 23/22; H01L 21/68785

(57) ABSTRACT

A ceramic heater includes: a ceramic plate having a wafer placement surface on its upper surface; two or more resistance heating elements embedded in the ceramic plate and provided for corresponding two or more divided zones of the wafer placement surface; a tubular shaft supporting the ceramic plate from a lower surface of the ceramic plate; a thermocouple insert hole provided in a shaft inner region that is a portion of the lower surface of the ceramic plate defined by the tubular shaft; and four or more resistance heating element terminal holes provided in the shaft inner region and corresponding to both ends of the two or more resistance heating elements. At least one of the two or more resistance heating elements is located above a bottom of the thermocouple insert hole and has a portion overlapping the thermocouple insert hole in plan view.

### BACKGROUND OF THE INVENTION

### 1. Field of the Invention

The present invention relates to a ceramic heater.

### 2. Description of the Related Art

A known ceramic heater includes a ceramic plate having a wafer placement surface on its upper surface, two resistance heating elements provided for corresponding two divided zones of the wafer placement surface, and a tubular shaft supporting the ceramic plate from the lower surface of the ceramic plate. For example, PTL 1 discloses a ceramic heater of this type that has a thermocouple insert hole and four terminal holes in a shaft inner region. The thermocouple insert hole is a hole to receive a thermocouple that measures the temperature of the middle area of the ceramic plate. The resistance heating elements are located above the bottom of the thermocouple insert hole. The four terminal holes are holes to receive power feeding rods that feed power to the resistance heating elements and are provided for the terminals of the two resistance heating elements.

### CITATION LIST

### Patent Literature

PTL 1: Japanese Unexamined Patent Application Publication No. 2021-125308

### SUMMARY OF THE INVENTION

However, in PTL 1, none of the two resistance heating elements overlap the thermocouple insert hole in plan view, and thus a portion of the wafer placement surface that is located directly above the thermocouple insert hole is likely to have a cool spot. The cool spot, which may lower the temperature uniformity of the wafer placement surface, is unfavorable.

The present invention was made to solve the above-described problem, and the main object thereof is to improve the temperature uniformity of a wafer placement surface.

[1] A ceramic heater of the present invention includes: a ceramic plate having a wafer placement surface on its upper surface; two or more resistance heating elements embedded in the ceramic plate and provided for corresponding two or more divided zones of the wafer placement surface; a tubular shaft supporting the ceramic plate from a lower surface of the ceramic plate; a thermocouple insert hole provided in a shaft inner region that is a portion of the lower surface of the ceramic plate defined by the tubular shaft; and four or more resistance heating element terminal holes provided in the shaft inner region and corresponding to both ends of the two or more resistance heating elements, wherein at least one of the two or more resistance heating elements is located above a bottom of the thermocouple insert hole and has a portion overlapping the thermocouple insert hole in plan view.

In this ceramic heater, at least one of the two or more resistance heating elements is located above the bottom of the thermocouple insert hole and has a portion overlapping the thermocouple insert hole in plan view. In other words, at least one of the resistance heating elements is positioned directly above the bottom of the thermocouple insert hole. This reduces the possibility that a portion of the wafer placement surface that is located directly above the thermocouple insert hole will have a cool spot. Thus, the wafer placement surface has higher temperature uniformity.

In this specification, “up” and “down” do not represent an absolute positional relationship but represents a relative positional relationship. Thus, “up” and “down” can be “down” and “up”, “left” and “right”, or “front” and “back” depending on the orientation of the ceramic heater.

[2] In the ceramic heater according to the present invention (the ceramic heater according to [1] above), a ratio of a depth of the thermocouple insert hole to a thickness of the ceramic plate from the wafer placement surface to the lower surface is preferably 0.055 or more and 0.4 or less. This further improves the temperature uniformity of the wafer placement surface.

[3] In the ceramic heater according to the present invention (the ceramic heater according to [1] or [2] above), in plan view, the thermocouple insert hole may be surrounded by four or more resistance heating element terminal holes. This enables the space between the resistance heating element terminal holes to be relatively large.

[4] In the ceramic heater according to the present invention (the ceramic heater according to any one of [1] to [3] above), the thermocouple insert hole preferably has a depth of 1 mm or more. This increases the reliability of the results of temperature measurement by a thermocouple.

[5] In the ceramic heater according to the present invention (the ceramic heater according to any one of [1] to [4] above), the tubular shaft preferably has an inner diameter of 52 mm or less. In this case, the area of the shaft inner region is so small that it is difficult to place the resistance heating elements around the thermocouple insert hole, and thus the application of this invention is highly significant.

[6] In the ceramic heater according to the present invention (the ceramic heater according to any one of [1] to [5] above), the ceramic plate may be an AlN plate. AlN, which has higher thermal conductivity than alumina and other materials, more readily makes the temperature of the wafer placement surface uniform.

[7] In the ceramic heater according to the present invention (the ceramic heater according to any one of [1] to [6] above), the ceramic plate may include a built-in functional electrode separate from the resistance heating element, the shaft inner region may have an electrode terminal hole provided for the functional electrode, and, in plan view, the thermocouple insert hole may be surrounded by the four or more resistance heating element terminal holes and the electrode terminal hole. In this case, an empty area of the shaft inner region is so small that it is difficult to place the resistance heating elements around the thermocouple insert hole, and thus the application of this invention is highly significant.

### BRIEF DESCRIPTION OF THE DRAWINGS

FIG. 1 is a perspective view of a ceramic heater 10.

FIG. 2 is a cross-sectional view taken along A-A in FIG. 1.

FIG. 3 is a partial magnified view of FIG. 2.

FIG. 4 is a cross-sectional view taken along B-B in FIG. 1.

FIG. 5 is a partial plan view of a wafer placement surface 21 of the ceramic heater 10.

FIG. 6 is a vertical cross-sectional view of a ceramic heater 110.

FIG. 7 is a partial plan view of a wafer placement surface 21 of the ceramic heater 110.

FIG. 8 is a partial plan view of a wafer placement surface 21 of another example.

### DETAILED DESCRIPTION OF THE INVENTION

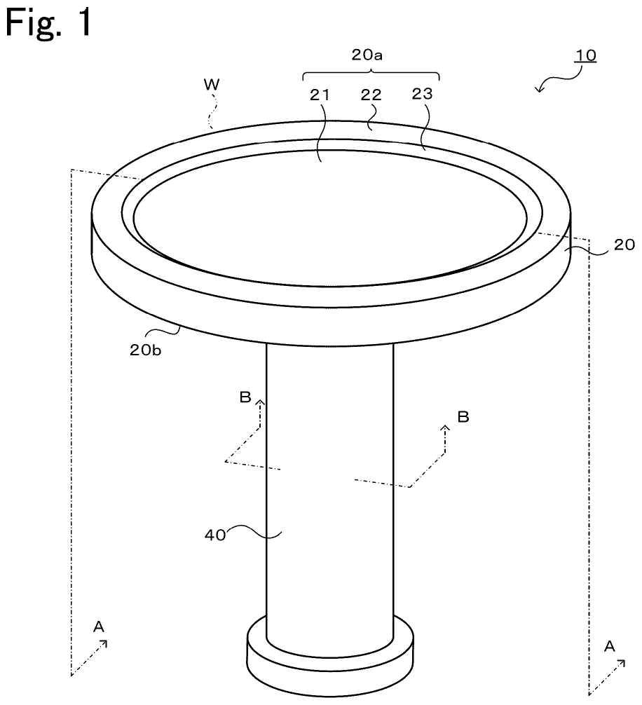

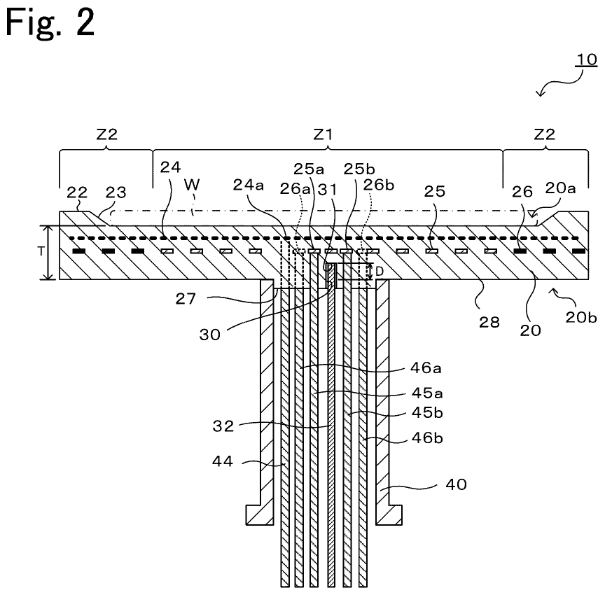

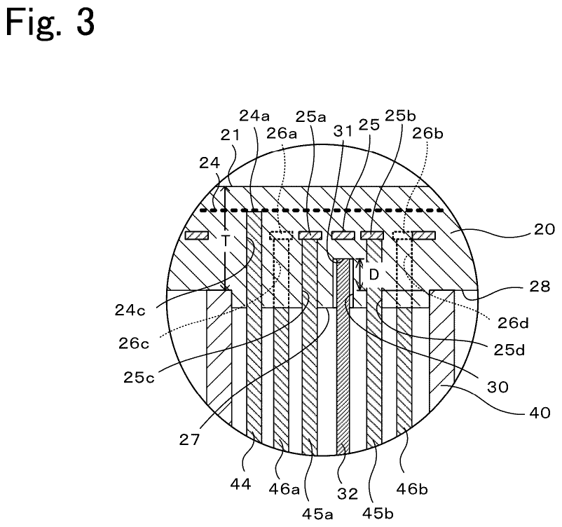

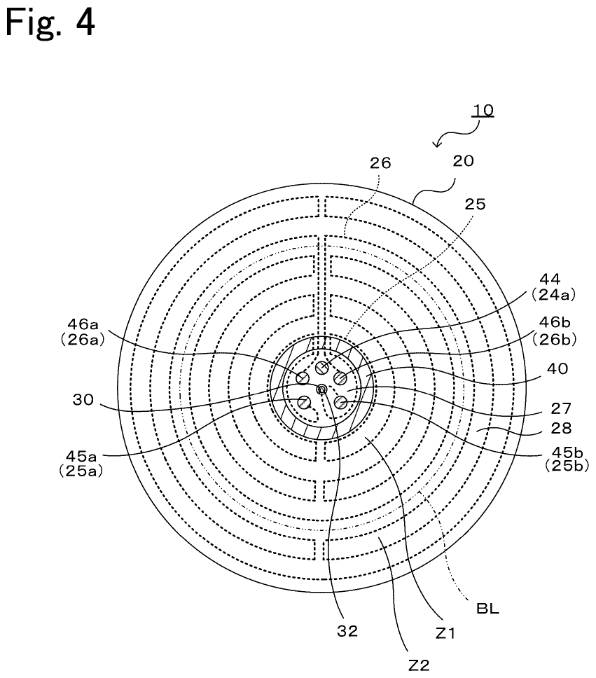

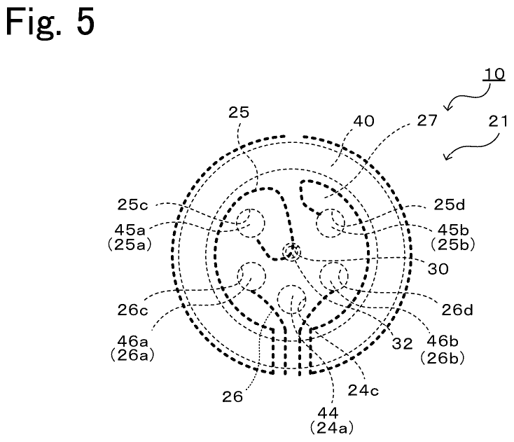

A preferred embodiment of the present invention will be described below with reference to the drawings. FIG. 1 is a perspective view of a ceramic heater 10, FIG. 2 is a partial cross-sectional view taken along A-A in FIG. 1, FIG. 3 is a partial magnified view of FIG. 2, FIG. 4 is a cross-sectional view taken along B-B in FIG. 1, and FIG. 5 is a partial plan view of a wafer placement surface 21 of the ceramic heater 10 (a plan view of a middle area of the wafer placement surface 21). Terminals 24a, 25a, 25b, 26a, and 26b are at the correct positions in FIGS. 4 and 5 but are shifted in the left and right direction in FIGS. 2 and 3 for convenience of explanation.

The ceramic heater 10, which is used to heat wafers W subjected to a process such as etching and CVD, is placed in a vacuum chamber (not illustrated). The ceramic heater 10 includes a ceramic plate 20 having a wafer placement surface 21 on its upper surface 20a and a tubular shaft 40 bonded to the lower surface 20b of the ceramic plate 20.

The ceramic plate 20 is a disc-shaped plate formed of a ceramic material, such as aluminum nitride and alumina. The ceramic plate 20 may have any diameter, for example, a diameter in a range of 300 to 400 mm. The upper surface 20a of the ceramic plate 20 includes a circular wafer placement surface 21, an annular surface 22 surrounding the wafer placement surface 21 and located slightly higher than the wafer placement surface 21, and a bank 23 that is a sloped surface between the wafer placement surface 21 and the annular surface 22. As illustrated in FIG. 2, the lower surface 20b of the ceramic plate 20 has a circular shaft inner region 27 defined by the tubular shaft 40 and an annular reference surface 28 surrounding the shaft inner region 27. The shaft inner region 27 protrudes downward from the reference surface 28.

An RF electrode 24, an inner-peripheral-side resistance heating element 25, and an outer-peripheral-side resistance heating element 26 are embedded in the ceramic plate 20. The inner-peripheral-side resistance heating element 25 and the outer-peripheral-side resistance heating element 26 are on the same plane below the RF electrode 24. The ceramic plate 20 has a small circular inner-peripheral-side zone Z1 and an annular outer-peripheral-side zone Z2 defined by a virtual boundary BL (see FIG. 4) that is concentric with the ceramic plate 20. The inner-peripheral-side resistance heating element 25 is embedded in the inner-peripheral-side zone Z1 of the ceramic plate 20, and the outer-peripheral-side resistance heating element 26 is embedded in the outer-peripheral-side zone Z2. The resistance heating elements 25 and 26 may be, for example, in the form of coil, mesh, foil, or ribbon (wire). The resistance heating elements 25 and 26 may be formed by printing. Examples of the material of the resistance heating elements 25 and 26 include Mo, W, Mo/W alloy, Nb, WC-TIN, and WC—Al₂O₃.

The tubular shaft 40 is formed of a ceramic material, such as aluminum nitride and alumina, like the ceramic plate 20. The outer diameter of the tubular shaft 40 is smaller than the diameter of the ceramic plate 20. The tubular shaft 40 is diffusion bonded to the ceramic plate 20 at the upper end. The upper end of the tubular shaft 40 may have a flange.

The RF electrode 24 is a circular electrode used to generate plasma above the wafer placement surface 21 and is formed of a metal mesh, for example. The RF electrode 24 has a smaller diameter than the ceramic plate 20. As illustrated in FIGS. 2 and 3, the RF electrode 24 has an RF electrode terminal 24a. As illustrated in FIG. 3, the RF electrode terminal 24a is exposed to the outside through an electrode terminal hole 24c in the shaft inner region 27. The RF electrode terminal 24a is connected to a bar-shaped RF rod 44 inserted in the electrode terminal hole 24c. Examples of the material of the RF electrode 24 include Mo, W, MoC, and WC. The RF electrode 24 is an example of a functional electrode of the present invention.

As illustrated in FIG. 4, the inner-peripheral-side resistance heating element 25 extends over almost the entire area of the inner-peripheral-side zone Z1 in a one-stroke pattern from one of the terminals 25a and 25b to the other of the terminals 25a and 25b while turning at multiple turnaround points. As illustrated in FIG. 3, the two terminals 25a and 25b of the inner-peripheral-side resistance heating element 25 are exposed to the outside through respective resistance heating element terminal holes 25c and 25d in the shaft inner region 27. The two terminals 25a and 25b are connected to bar-shaped power feeding rods 45a and 45b in the respective resistance heating element terminal holes 25c and 25d.

As illustrated in FIG. 4, the outer-peripheral-side resistance heating element 26 extends over almost the entire area of the outer-peripheral-side zone Z2 in a one-stroke pattern from one of the terminals 26a and 26b to the other of the terminals 26a and 26b while turning at multiple turnaround points. As illustrated in FIG. 3, the two terminals 26a and 26b of the outer-peripheral-side resistance heating element 26 are exposed to the outside through respective resistance heating element terminal holes 26c and 26d in the shaft inner region 27. The two terminals 26a and 26b are connected to bar-shaped power feeding rods 46a and 46b in the respective resistance heating element terminal holes 26c and 26d. The inner-peripheral and outer-peripheral-side resistance heating elements 25 and 26 bypass the RF rod 44 to avoid contact with the RF rod 44.

The tubular shaft 40 houses, as illustrated in FIG. 2, the power feeding rods 45a and 45b, which are connected to the respective terminals 25a and 25b of the inner-peripheral-side resistance heating element 25, and the power feeding rods 46a and 46b, which are connected to the respective terminals 26a and 26b of the outer-peripheral-side resistance heating element 26. The power feeding rods 45a and 45b are connected to a heater power supply (not illustrated) for the inner-peripheral-side resistance heating element 25, and the power feeding rods 46a and 46b are connected to a heater power supply (not illustrated) for the outer-peripheral-side resistance heating element 26. The tubular shaft 40 also houses a thermocouple 32 for measuring the temperature near a central portion of the ceramic plate 20. The thermocouple 32 is a sheathed thermocouple for example. The thermocouple 32 is inserted in a thermocouple insert hole 30 in the shaft inner region 27 of the ceramic plate 20 and is in contact with the ceramic plate 20 (the bottom 31 of the thermocouple insert hole 30) at the tip temperature measuring portion. The inner-peripheral-side and outer-peripheral-side resistance heating elements 25 and 26 are located above the bottom 31 of the thermocouple insert hole 30. Conversely, the bottom 31 of the thermocouple insert hole 30 is located below the inner-peripheral-side and outer-peripheral-side resistance heating elements 25 and 26. As illustrated in FIG. 5, the inner-peripheral-side resistance heating element 25 crosses the thermocouple insert hole 30 in plan view. In other words, the inner-peripheral-side resistance heating element 25 is positioned directly above the bottom 31 of the thermocouple insert hole 30. In this case, a portion of the inner-peripheral-side resistance heating element 25 that crosses the thermocouple insert hole 30 is the portion that overlaps the thermocouple insert hole 30. Furthermore, in plan view, the thermocouple insert hole 30 is surrounded by the four resistance heating element terminal holes 25c, 25d, 26c, and 26d, and the RF electrode terminal hole 24c.

The ratio of the depth D of the thermocouple insert hole 30 (see FIGS. 2 and 3) to the thickness T of the ceramic plate 20 from the wafer placement surface 21 to the reference surface 28 of the lower surface 20b (see FIGS. 2 and 3) is preferably 0.055 or more and 0.4 or less. This can reduce the difference between the highest temperature and the lowest temperature of the wafer placement surface 21. The depth D is the distance from the bottom 31 of the thermocouple insert hole 30 to the reference surface 28 included in the lower surface 20b of the ceramic plate 20. The depth D of the thermocouple insert hole 30 is preferably 1 mm or more. Furthermore, the inner diameter of the tubular shaft 40 is preferably 52 mm or less.

Next, a usage example of the ceramic heater 10 will be described. First, the ceramic heater 10 is disposed in a vacuum chamber (not illustrated), and then a wafer W is placed on the wafer placement surface 21 of the ceramic heater 10. In the vacuum chamber, an upper electrode for plasma generation is placed above the wafer placement surface 21. Then, the power supplied to each of the inner-peripheral-side resistance heating element 25 and the outer-peripheral-side resistance heating element 26 is adjusted so that the temperature detected by the thermocouple 32 becomes a predetermined target temperature. In this way, the temperature of the wafer W is controlled to achieve a desired temperature. Then, settings are adjusted such that the interior of the vacuum chamber becomes a vacuum atmosphere or a reduced-pressure atmosphere, and plasma is produced in the vacuum chamber. The plasma is used to form a CVD film on the wafer W or to perform etching. Plasma is generated by grounding one of the upper electrode and the RF electrode 24 and applying RF voltage to the other.

In the above-described ceramic heater 10, the inner-peripheral-side resistance heating element 25 is positioned above the bottom 31 of the thermocouple insert hole 30 and has a portion that overlaps the thermocouple insert hole 30 in plan view. In other words, the inner-peripheral-side resistance heating element 25 is positioned directly above the bottom 31 of the thermocouple insert hole 30. This reduces the possibility that a portion of the wafer placement surface 21 that is located directly above the thermocouple insert hole 30 will have a cool spot. Thus, the wafer placement surface 21 has higher temperature uniformity.

The ratio of the depth D of the thermocouple insert hole 30 to the thickness T of the ceramic plate 20 is preferably 0.055 or more and 0.4 or less. This further improves the temperature uniformity of the wafer placement surface 21. The ratio is more preferably 0.055 or more and 0.3 or less, and further more preferably 0.055 or more and 0.28 or less.

Furthermore, in plan view, the thermocouple insert hole 30 is surrounded by the four resistance heating element terminal holes 25c, 25d, 26c, and 26d, and the RF electrode terminal hole 24c. This enables the space between the terminal holes to be relatively large, resulting in less short circuit between the terminals and between the rods.

Furthermore, the depth D of the thermocouple insert hole 30 is preferably 1 mm or more. This increases the reliability of the results of temperature measurement by the thermocouple 32.

Furthermore, the inner diameter of the tubular shaft 40 is preferably 52 mm or less. In this case, the area of the shaft inner region 27 is so small that it is difficult to place the inner-peripheral-side and outer-peripheral-side resistance heating elements 25 and 26 around the thermocouple insert hole 30, and thus the application of this invention is highly significant.

Furthermore, the ceramic plate 20 is preferably an AlN plate. AlN, which has higher thermal conductivity than alumina or other materials, more readily makes the temperature of the wafer placement surface 21 uniform.

The present invention should not be limited to the above-described embodiment and may be implemented in various modes without departing from the technical scope of the present invention.

For example, in the above-described embodiment, the RF electrode 24 is embedded in the ceramic plate 20, but the RF electrode 24 may be omitted. Alternatively, an electrostatic electrode may be embedded in the ceramic plate 20 instead of or in addition to the RF electrode 24. The electrostatic electrode is another example of a functional electrode of the present invention. The electrostatic electrode is embedded in the ceramic plate 20 at a position closest to the wafer placement surface 21. The electrostatic electrode has an electrostatic electrode terminal on its lower surface, and the electrostatic electrode terminal is exposed to the outside through an electrostatic electrode terminal hole in the shaft inner region 27. The electrostatic electrode terminal is then connected to a bar-shaped power feeding rod that is inserted in the electrostatic electrode terminal hole. The electrostatic electrode is not in contact with the inner-peripheral-side and outer-peripheral-side resistance heating elements 25 and 26, and the RF electrode 24. When DC voltage is applied to the electrostatic electrode via the power feeding rod, the wafer W is attracted and fixed to the wafer placement surface 21.

In the above-described embodiment, the thermocouple insert hole 30 is surrounded by the four resistance heating element terminal holes 25c, 25d, 26c, and 26d, and the RF electrode terminal hole 24c in plan view, but this should not be construed as limiting. For example, the thermocouple insert hole 30 may be located outside the area defined by the four resistance heating element terminal holes 25c, 25d, 26c, and 26d, and the RF electrode terminal hole 24c.

In the above-described embodiment, the inner-peripheral-side resistance heating element 25 crosses the thermocouple insert hole 30 in plan view, but the outer-peripheral-side resistance heating element 26 may cross the thermocouple insert hole 30 in plan view. Alternatively, as illustrated in FIG. 8, in plan view, the thermocouple insert hole 30 may have an edge that is positioned in the width range of the inner-peripheral-side resistance heating element 25. In the case of FIG. 8, the shaded portion indicates the portion of the inner-peripheral-side resistance heating element 25 that overlaps the thermocouple insert hole 30. Although the configuration in FIG. 8 allows the wafer placement surface 21 to have higher temperature uniformity, the temperature uniformity is further higher in the above-described embodiment.

In the above-described embodiment, a so-called two-zone heater was illustrated, but this should not be construed as limiting, and any heater including two or more resistance heating elements may be employed. For example, the inner-peripheral-side zone Z1 may be divided into multiple small inner-peripheral-side zones, and each of the small inner-peripheral-side zones may have a resistance heating element extending in a one-stroke pattern. The outer-peripheral-side zone Z2 may be divided into multiple small outer-peripheral-side zones, and each of the small outer-peripheral-side outer zones may have a resistance heating element extending in a one-stroke pattern.

In the above-described embodiment, the shaft inner region 27 of the lower surface 20b of the ceramic plate 20 protrudes downward from the surrounding reference surface 28, but the shaft inner region 27 may be flush with the reference surface 28.

### EXAMPLES

### Experimental Examples 1 to 8

In each of Experimental Examples 1 to 8, the ceramic heater 10 illustrated in FIGS. 1 to 5 was produced. Specifically, a plate formed of sintered aluminum nitride having a diameter ø of 330 mm was used as the ceramic plate 20. A shaft formed of sintered aluminum nitride and having a wall thickness of 3 mm was used as the tubular shaft 40. The inner-peripheral-side and outer-peripheral-side resistance heating elements 25 and 26 were formed of Mo. Table 1 shows the depth D of the thermocouple insert hole (TC hole) 30, the thickness T of the ceramic plate 20, the ratio D/T, the presence or absence of the heating element over the TC hole 30, and the inner diameter of the tubular shaft 40.

The temperature uniformity was evaluated in Experimental Examples 1 to 8 as follows. The central temperature of a wafer W placed on the wafer placement surface 21 without plasma treatment was set to the target temperature (550° C. in this case), the inside of the vacuum chamber was set to 5 torr under nitrogen atmosphere, the surface temperature of the entire wafer W was measured by using an infrared camera, and the difference between the highest temperature and the lowest temperature was used as the value of temperature uniformity. Table 1 indicates the results.

### Experimental Examples 9 to 12

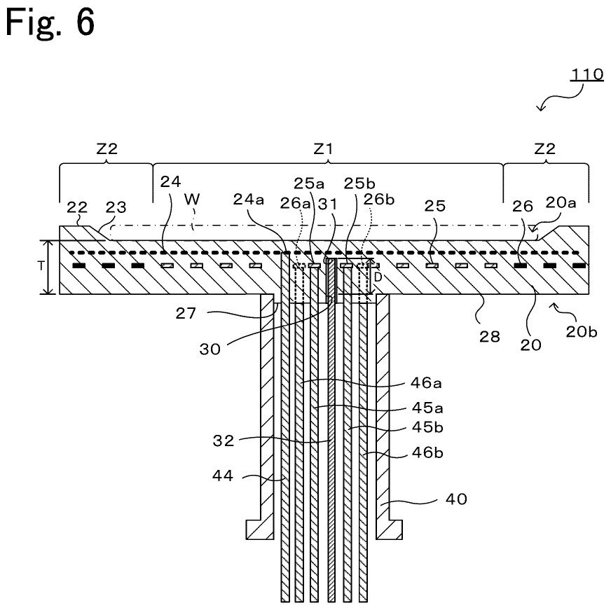

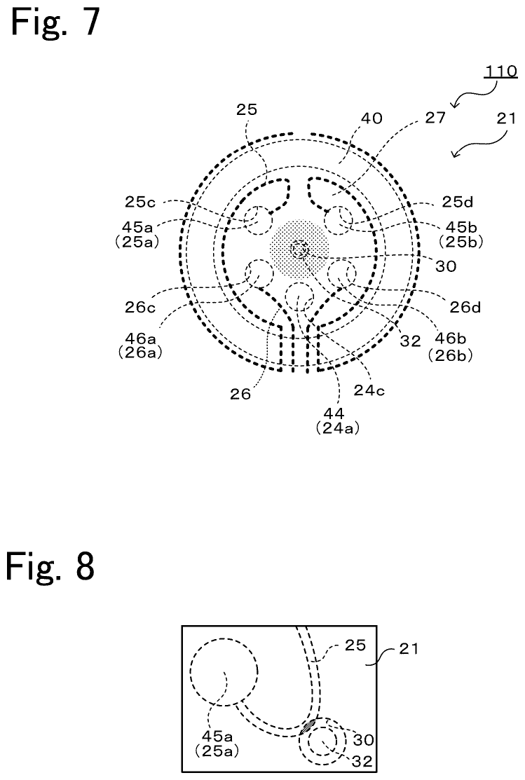

In each of Experimental Examples 9 to 12, the ceramic heater 110 illustrated in FIGS. 6 and 7 was produced. In FIGS. 6 and 7, the same symbols are assigned to the same components as those in the above-described embodiment. The ceramic heater 110 is the same as the ceramic heater 10 except for that the inner-peripheral-side and outer-peripheral-side resistance heating elements 25 and 26 are located below the bottom 31 of the thermocouple insert hole 30 and located such that they do not cross the thermocouple insert hole 30 and bypass it in plan view. In Experimental Examples 9 to 12, a plate formed of sintered aluminum nitride having a diameter ø of 330 mm was used as the ceramic plate 20. A shaft formed of sintered aluminum nitride and having a wall thickness of 3 mm was used as the tubular shaft 40. The inner-peripheral-side and outer-peripheral-side resistance heating elements 25 and 26 were formed of Mo. Table 1 indicates the depth D of the TC hole 30, the thickness T of the ceramic plate 20, the ratio D/T, the presence or absence of the heating element over the TC hole 30, and the inner diameter of the tubular shaft 40.

The temperature uniformity was evaluated in Experimental Examples 9 to 12 in the same manner as in Experimental Examples 1 to 8. Table 1 indicates the results.

TABLE 1

| | | | | Presence or | | |
|---|---|---|---|---|---|---|
| | Depth D of | Thickness T | | absence of heating | Inner diameter | |
| Experimental | TC hole | of plate | | element over TC | of shaft | Temperature |
| Example | (mm) | (mm) | Ratio D/T | hole | (mm) | uniformity *¹ |
| 1 | 2.5 | 14.2 | 0.176 | Presence | 36 | 2.1 |
| 2 | 1.5 | 14.2 | 0.106 | Presence | 36 | 2.3 |
| 3 | 2.5 | 10.2 | 0.245 | Presence | 36 | 2.8 |
| 4 | 5.0 | 18.0 | 0.278 | Presence | 39 | 2.5 |
| 5 | 1.0 | 18.2 | 0.055 | Presence | 39 | 1.9 |
| 6 | 1.5 | 22.0 | 0.068 | Presence | 52 | 2.0 |
| 7 | 1.5 | 24.8 | 0.060 | Presence | 52 | 2.2 |
| 8 | 0.5 | 15.0 | 0.033 | Presence | 36 | 4.4 |
| 9 | 8.0 | 14.2 | 0.563 | Absence | 36 | 5.9 |
| 10 | 12.0 | 18.2 | 0.659 | Absence | 36 | 6.1 |
| 11 | 14.0 | 18.0 | 0.778 | Absence | 39 | 5.4 |
| 12 | 10.0 | 16.2 | 0.617 | Absence | 52 | 6.6 |

*¹ Temperature uniformity = The difference between the highest temperature and the lowest temperature of the wafer placement surface

As shown in Table 1, in Experimental Examples 1 to 8, where the inner-peripheral-side resistance heating element 25 crosses the TC hole 30 in plan view, the values of temperature uniformity were smaller (higher temperature uniformity) than those in Experimental Examples 9 to 12, where the inner-peripheral-side and outer-peripheral-side resistance heating elements 25 and 26 do not cross the TC hole 30 in plan view. In Experimental Examples 1 to 12, the inner diameter of each of the tubular shafts 40 was 52 mm or less. In the ceramic heaters 110 of Experimental Examples 9 to 12 (FIGS. 6 and 7), the use of the tubular shaft 40 having an inner diameter of 52 mm or less makes the value of temperature uniformity large, because the area of the shaft inner region 27 is so small that it does not allow easy positioning of the resistance heating elements around the TC hole 30. Specifically, the temperature of the substantially circular area centered on the TC hole 30 (shaded area in FIG. 7) was low.

In Experimental Examples 1 to 7, where the ratios D/T were in a range of 0.055 or more and 0.4 or less, the values of temperature uniformity were smaller than that of Experimental Example 8, where the ratio D/T was 0.033. Furthermore, in Experimental Examples 1 to 7, where the depths D of the TC hole 30 were 1 mm or more, the temperature was more stably measured by the thermocouple 32 than in Experimental Example 8, where the depth D of the TC hole 30 was 0.5 mm.

The upper limit of the thickness T of the ceramic plate 20 is preferably 25 mm to prevent damage during being fired.

Experimental Examples 1 to 8 correspond to Examples of the invention, and Experimental Examples 9 to 12 correspond to Comparative Examples. It should be understood that these Examples do not limit the present invention.

International Application No. PCT/JP2023/042804, filed on Nov. 29, 2023, is incorporated herein by reference in its entirety.

What is claimed is:

1. A ceramic heater comprising:
a ceramic plate having a wafer placement surface on its upper surface;
two or more resistance heating elements embedded in the ceramic plate and provided for corresponding two or more divided zones of the wafer placement surface;
a tubular shaft supporting the ceramic plate from a lower surface of the ceramic plate;
a thermocouple insert hole provided in a shaft inner region that is a portion of the lower surface of the ceramic plate defined by the tubular shaft; and
four or more resistance heating element terminal holes provided in the shaft inner region and corresponding to both ends of the two or more resistance heating elements, wherein
at least one of the two or more resistance heating elements is located above a bottom of the thermocouple insert hole and has a portion overlapping the thermocouple insert hole in plan view, and
a ratio of a depth of the thermocouple insert hole to a thickness of the ceramic plate from the wafer placement surface to the lower surface is 0.055 or more and 0.4 or less.

2. The ceramic heater according to claim 1, wherein, in plan view, the thermocouple insert hole is surrounded by the four or more resistance heating element terminal holes.

3. The ceramic heater according to claim 1, wherein the thermocouple insert hole has a depth of 1 mm or more.

4. The ceramic heater according to claim 1, wherein the tubular shaft has an inner diameter of 52 mm or less.

5. The ceramic heater according to claim 1, wherein the ceramic plate is an AlN plate.

6. The ceramic heater according to claim 1, wherein the ceramic plate includes a built-in functional electrode separate from the resistance heating element,
the shaft inner region has an electrode terminal hole provided for the functional electrode, and
in plan view, the thermocouple insert hole is surrounded by the four or more resistance heating element terminal holes and the electrode terminal hole.
